(19) United States
(12) Patent Application Publication
(10) Pub. No.: US 2015/0327395 A1
(43) Pub. Date: Nov. 12, 2015

(54) APPARATUS FOR SECURING AN ELECTRONIC COMPONENT

(71) Applicant: General Electric Company, Schenectady, NY (US)

(72) Inventors: DANIEL TUTTLE SPENCER, LAWRENCE PARK, PA (US); MARK ALLEN MURPHY, ERIE, PA (US); MATTHEW HART, LAWRENCE PARK, PA (US); MICHAEL BOOTH, LAWRENCE PARK, PA (US)

(73) Assignee: GENERAL ELECTRIC COMPANY, Schenectady, NY (US)

(21) Appl. No.: 14/683,970

(22) Filed: Apr. 10, 2015

Related U.S. Application Data
(60) Provisional application No. 61/990,760, filed on May 9, 2014.

(51) Int. Cl. H05K 7/20; H05K 5/02

(52) U.S. Cl. CPC H05K 7/2039; H05K 5/0217

(57) ABSTRACT

An apparatus for securing an electronic component to a heat sink or other support structure includes an insulative housing including a main body portion and a pair of opposed depending legs. The main body portion has a central recess formed therein. A pivot block or fulcrum is disposed in the recess. The apparatus also includes a load bar that is engageable with the pivot block to exert a compressive force upon the pivot block.

### CROSS-REFERENCE TO RELATED APPLICATIONS

This application claims the benefit of U.S. Provisional Application Ser. No. 61/990,760, filed on May 9, 2014, which is herein incorporated by reference in its entirety.

### FIELD OF THE INVENTION

Embodiments of the invention relate generally to electronic devices. Other embodiments relate to an apparatus for clamping semiconductor devices and associated components.

### BACKGROUND OF THE INVENTION

High-powered semiconductor devices, such as diodes, thyristors and semiconductor-controlled rectifiers (SCRs), must be cooled to prevent failure caused by overheating. Typically, heat dissipating devices, such as heat sinks or chill blocks, are clamped to the semiconductor device to dissipate the heat generated by the semiconductor. It is essential that uniform, intimate contact be obtained between the heat dissipating devices and the semiconductor, and this requires that the pieces are clamped parallel to each other within the tolerance limit to which the corresponding semiconductor surfaces are parallel.

One of the disadvantages associated with existing clamping devices is overtightening and uneven application of clamping forces. Overtightening may cause the shapes of the semiconductor device and the heat dissipating device to distort. This distortion may cause the interface between the semiconductor device and the heat dissipating devices to become skewed, which decreases the contact surface area between the two, thus reducing heat transfer from the semiconductor to the heat dissipating device.

Another disadvantage associated with existing clamping devices is that the semiconductor device may be located or become positioned off-center from the clamp jaws. This also reduces the contact surface area between the semiconductor device and the heat dissipating device, which results in reduced heat transfer.

Moreover, existing clamping devices may not meet electrical creepage and gap distance requirements for certain industry applications.

### BRIEF DESCRIPTION OF THE INVENTION

In an embodiment, an apparatus (e.g., an apparatus for securing an electronic component to a heat sink or other support structure) includes a pivot block, a load bar, and an insulative housing having a body portion and a pair of opposed depending legs attached to the body portion. The body portion has a central recess formed therein. The pivot block is configured to be disposed in the recess. The load bar engageable with the pivot block.

In another embodiment, an electronic device includes a support, an electronic component operably coupled to the support, and a clamping apparatus for clamping the electronic component to the support. The clamping apparatus includes a pivot block, a load bar, and an insulative housing having a body portion and a pair of opposed depending legs. The body portion has a central recess formed therein, with the pivot block being disposed in the recess. The load bar is engageable with the pivot block.

In yet another embodiment, an electronic device is provided. The electronic device includes a pivot block, a load bar, and an insulative housing having a body portion and a pair of opposed depending legs attached to the body portion. The body portion has a central recess formed therein. The pivot block is disposed in the recess. The load bar is engageable with the pivot block. The body portion includes a generally cylindrical center portion and a pair of distal arms arranged on opposing sides of the center portion. The opposed depending legs are respectively attached to the distal arms. The opposed depending legs and distal arms define respective passageways that extend through the opposed depending legs and distal arms. The load bar defines a pair of opposed throughbores that are spaced apart by a first distance corresponding to a second distance between the passageways of the opposed depending legs and distal arms. The load bar includes a detent formed in an underside thereof, and the pivot block includes a domed top having an apex configured to be received by the detent. The electronic device also includes a heat sink having two apertures spaced apart from one another by a third distance that corresponds to the first and second distances, an electronic component operably coupled to the heat sink between the two apertures, and first and second fasteners. The load bar engages the pivot block, with the apex of the domed top of the pivot block being received in the detent of the load bar. The first and second fasteners are respectively positioned through the opposed throughbores of the load bar, through the passageways of the opposed depending legs and distal arms, and through the apertures of the heat sink, for attaching the apparatus to the heat sink such that the load bar presses on the pivot block, the pivot block presses on the housing body portion, and the body portion clamps the electronic component to the heat sink.

### BRIEF DESCRIPTION OF THE DRAWINGS

The present invention will be better understood from reading the following description of non-limiting embodiments, with reference to the attached drawings, wherein below:

FIG. 1 is perspective view of an apparatus for securing an electronic component, according to an embodiment of the invention.

FIG. 2 is a top, plan view of the apparatus of FIG. 1.

FIG. 3 is an exploded, perspective view of the apparatus of FIG. 1.

FIG. 4 is a perspective view of an insulative housing of the apparatus of FIG. 1.

FIG. 5 is a front, elevational view of the housing of FIG. 4.

FIG. 6 is a top, plan view of the housing of FIG. 4.

FIG. 7 is a perspective view of a pivot block of the apparatus of FIG. 1.

FIG. 8 is a top, perspective view of a load bar of the apparatus of FIG. 1.

FIG. 9 is a bottom, perspective view of the load bar of FIG. 8.

FIG. 10 an exploded, perspective view of the apparatus of FIG. 1, illustrating fasteners for securing the apparatus to a support structure.

FIG. 11 is a partially exploded, perspective view of the apparatus of FIG. 1, illustrating fasteners for securing the apparatus to a support structure.

FIG. 12 is a partially exploded, bottom, perspective view of the apparatus of FIG. 1.

FIG. 13 is a cross-sectional, schematic diagram of the apparatus of FIG. 1, illustrating the clamping of an electronic component to a heat sink in accordance with an embodiment of the invention.

FIG. 14 is a perspective view of an embodiment of a power semiconductor clamp.

FIG. 15 is a front elevational view of the power semiconductor clamp of FIG. 14, the rear being a mirror image.

FIG. 16 is a right side elevational view of the power semiconductor clamp of FIG. 14, the left side being a mirror image.

FIG. 17 is a top plan view of the power semiconductor clamp of FIG. 14.

FIG. 18 is a bottom plan view of the power semiconductor clamp of FIG. 14.

FIG. 19 is a perspective view of another embodiment of a power semiconductor clamp.

FIG. 20 is a front elevational view of the power semiconductor clamp of FIG. 19, the rear being a mirror image.

FIG. 21 is a right side elevational view of the power semiconductor clamp of FIG. 19, the left side being a mirror image.

FIG. 22 is a top plan view of the power semiconductor clamp of FIG. 19.

FIG. 23 is a bottom plan view of the power semiconductor clamp of FIG. 19.

FIG. 24 is a perspective view of another embodiment of a power semiconductor clamp.

FIG. 25 is a front elevational view of the power semiconductor clamp of FIG. 24, the rear being a mirror image.

FIG. 26 is a right side elevational view of the power semiconductor clamp of FIG. 24, the left side being a mirror image.

FIG. 27 is a top plan view of the power semiconductor clamp of FIG. 24.

FIG. 28 is a bottom plan view of the power semiconductor clamp of FIG. 24.

FIG. 29 is a perspective view of a pivot block of the power semiconductor clamp of FIG. 24.

FIG. 30 is a front elevational view of the pivot block of FIG. 29, the rear, the left side, and the right side being mirror images.

FIG. 31 is a top plan view of the pivot block of FIG. 29.

FIG. 32 is a bottom plan view of the pivot block of FIG. 29.

FIG. 33 is a perspective view of a load bar of the power semiconductor clamp of FIG. 24.

FIG. 34 is a right side elevational view of the load bar of FIG. 33, the left side being a mirror image.

FIG. 35 is a front elevational view of the load bar of FIG. 33, the rear being a mirror image.

FIG. 36 is a bottom plan view of the load bar of FIG. 33.

FIG. 37 is a top plan view of the load bar of FIG. 33.

### DETAILED DESCRIPTION OF THE INVENTION

Reference will be made below in detail to exemplary embodiments of the invention, examples of which are illustrated in the accompanying drawings. Wherever possible, the same reference numerals used throughout the drawings refer to the same or like parts.

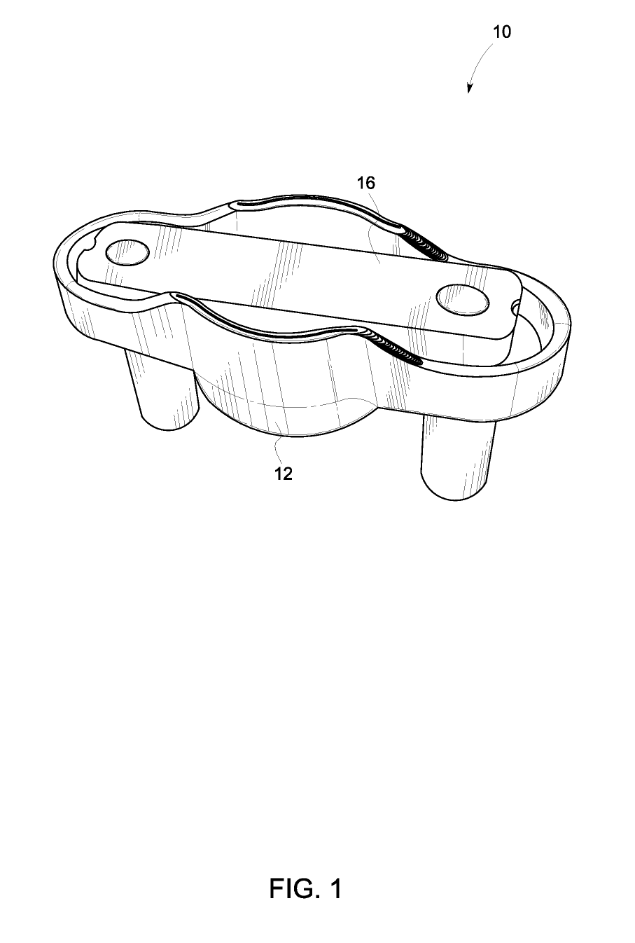

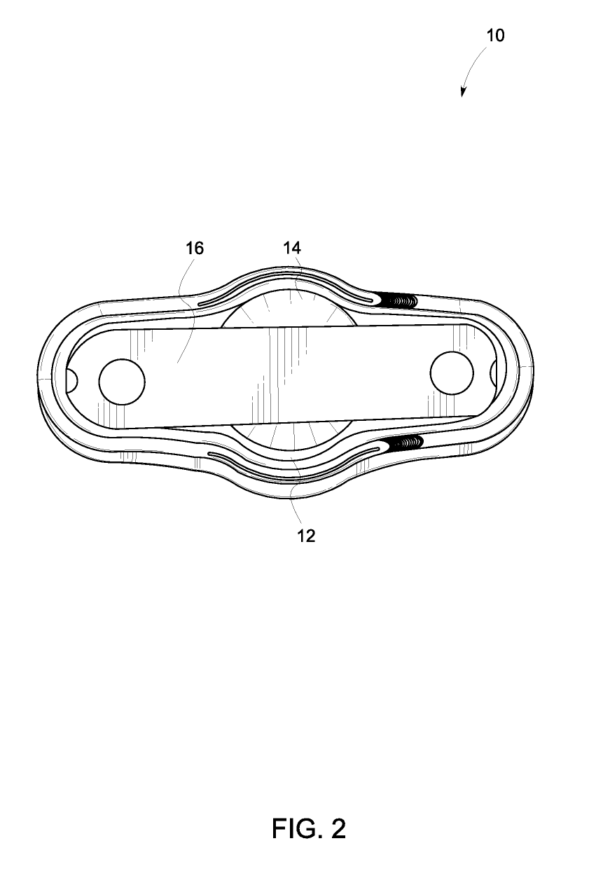

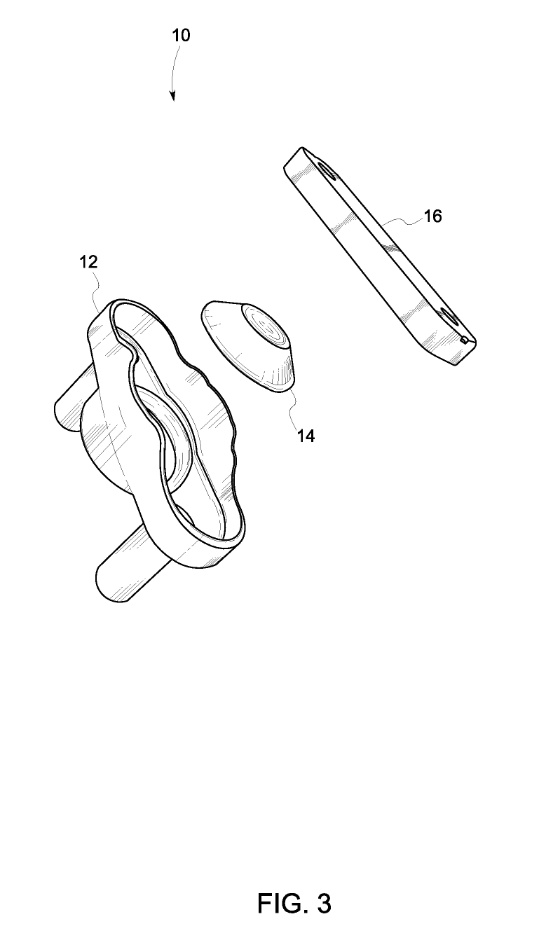

Turning to FIGS. 1-3, embodiments of the invention relate to an apparatus 10 for securing a power semiconductor or other electronic component to an electronic device. As used herein, “electronic component” refers to a component, discrete or otherwise, which is configured to affect electricity or its related fields. “Electronic device” refers to a device that includes one or more electronic components and a housing and/or support for housing and/or supporting, respectively, the one or more electronic components. “Power semiconductor” means any semiconductor electronic component that is configured for use (e.g., as a switch or rectifier) to control the provision of electrical power in a power electronic circuit, and may include, but is not limited to, a power diode, power MOSFET, insulated gate bipolar transistor (IGBT), or thyristor, such as a silicon or semiconductor-controlled rectifier (SCR). As shown in FIGS. 1-3, the apparatus 10 includes an insulative housing 12, a pivot block 14, and a load bar 16. The pivot block 12 is shaped to be disposed within the housing 12 and cooperates with the load bar 16 (when the apparatus is assembled for use) to provide a clamping force on a power semiconductor or other electronic component, as discussed in detail below.

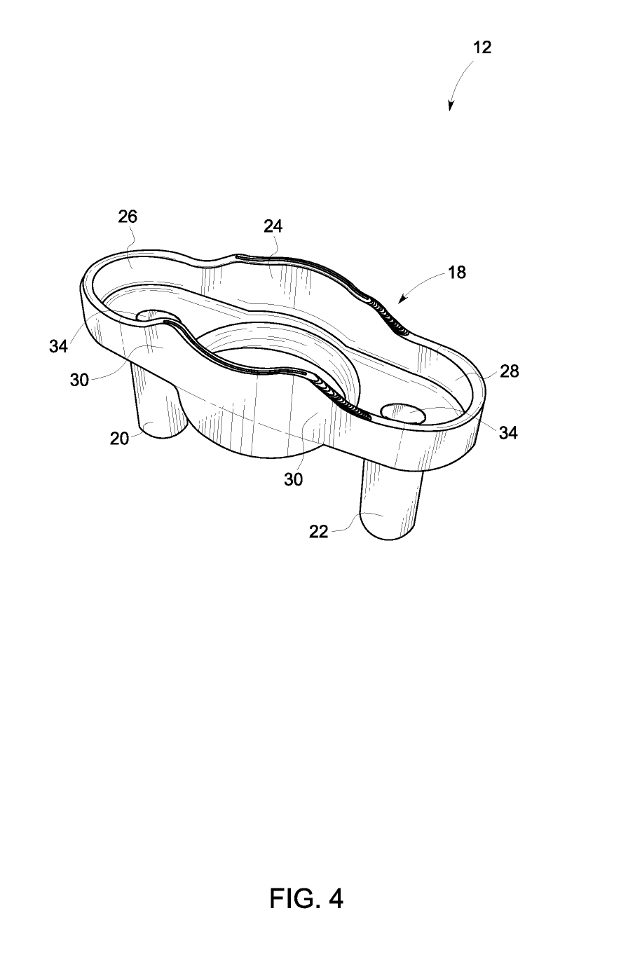

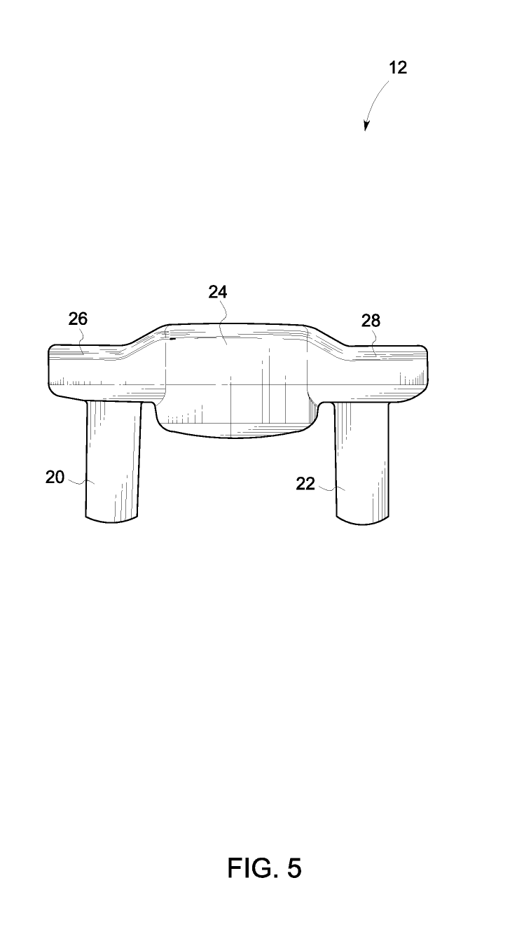

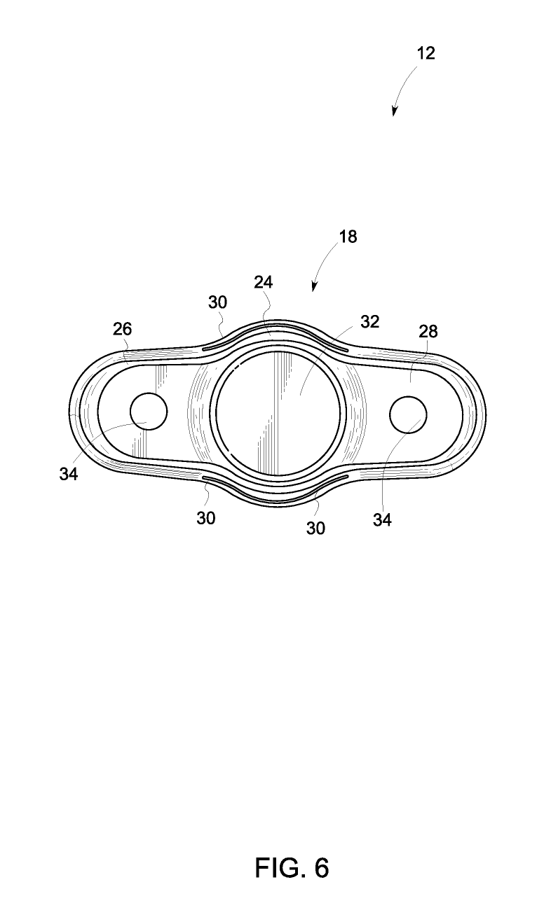

With particular reference to FIGS. 4-6, the insulative housing 12 includes a body portion 18 and two downwardly depending legs 20, 22. The body portion 18 is defined by a generally cylindrical center portion 24 and a pair of distal arms 26, 28 arranged on opposing sides of the center portion 24 and extending therefrom. The distal arms 26, 28 are integrally formed with the center portion 24 and joined thereto at filleted corners 30 such that the center portion 24 and distal arms 26, 28 form an interior cavity having an open top. As best shown in FIG. 6, the distal arms 26, 28 have a diameter that is smaller than a diameter of the center portion 24. As best shown in FIG. 4, the cylindrical center portion 24 has a floor that is oriented lower relative to the respective floors of the distal arms 26, 28 and which thereby defines a recess or boss 32 for retaining the pivot block 14, as discussed in detail hereinafter. As shown in FIG. 5, the top rim of the center portion 24 forms a plateau that is oriented higher than a top rim of the respective distal arms 26, 28. The legs 20, 22 depend from the distal arms 26, 28, respectively, and are integrally formed therewith. With further reference to FIG. 6, the legs 20, 22 each define a respective passageway 34 therethrough for accommodating suitable fasteners 50, such as bolts, as also discussed hereinafter. As should be appreciated, the passageways 34 also pass through the respective floors of the distal arms 26, 28.

In an embodiment, the insulative housing 12 is formed from plastic or other suitable insulative material sufficient to minimize the risk of mechanical creep under anticipated operating load and temperature conditions. This facilitates the maintenance of the desired clamp load throughout the life of the electronic component.

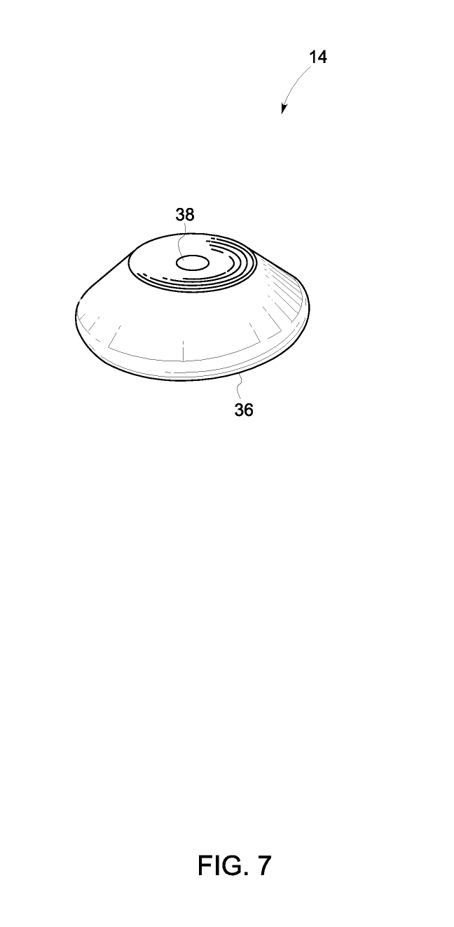

Turning now to FIG. 7, the pivot block 14 takes the form of a truncated cone or conical frustum having a substantially planar base 36 and a slightly arcuate or domed top 38. The pivot block 14 is configured to consistently locate itself with respect to the housing 12 and the load bar 16, facilitating ease of assembly. In particular, the base 36 of the pivot block 14 is sized to be closely received and retained in boss 32 in the insulative housing 12. For example, in an embodiment, the base 36 has a diameter that is slightly less than the diameter of the boss 32 in the housing 12. In an embodiment, the pivot block 14 is formed from a material with a hardness sufficient to substantially resist deformation under typical applied loads. In an embodiment, the pivot block 14 is formed from metal. In various embodiments, the pivot block 14 may be a solid body.

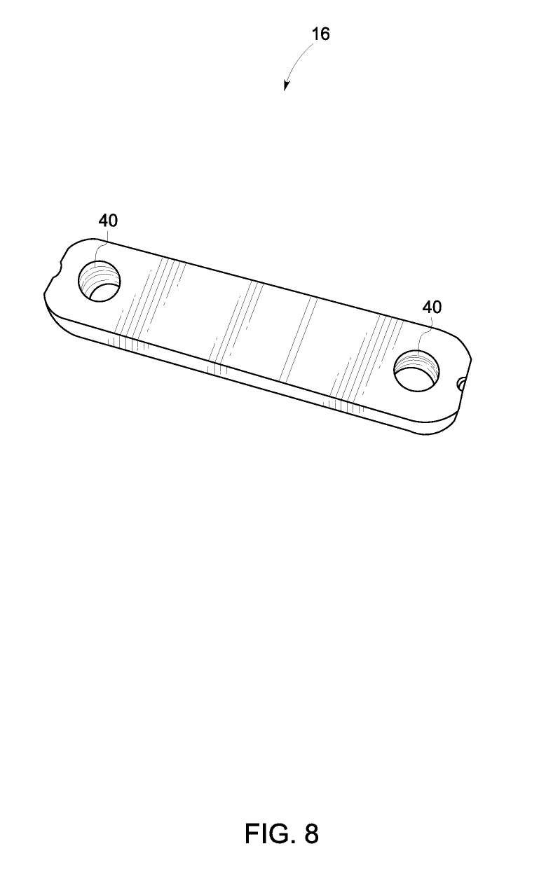

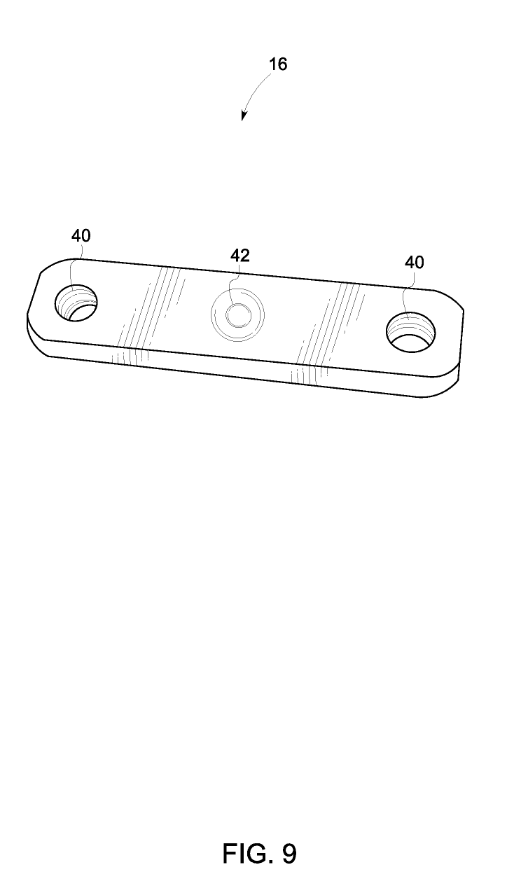

Referring now to FIGS. 8 and 9, the load bar 16 is generally rectangular in shape and includes a pair of opposed throughbores 40. The spacing between the throughbores 40 is substantially identical to the spacing between the passageways 34 in the legs 20, 22 of the housing 12 such that the throughbores 40 in the load bar 16 and the passageways 34 in the legs 20, 22 are aligned when the apparatus 10 is assembled. As best shown in FIG. 9, the load bar 16 includes a detent 42 on the underside surface thereof that is configured to receive the apex of the domed top 38 of the pivot block 14. In an embodiment, the load bar 16 is formed from a material with a yield stress substantially greater than the stress seen during operation and is resistant to hydrogen embrittlement. In an embodiment, the load bar 16 is formed from a metal such as stainless steel.

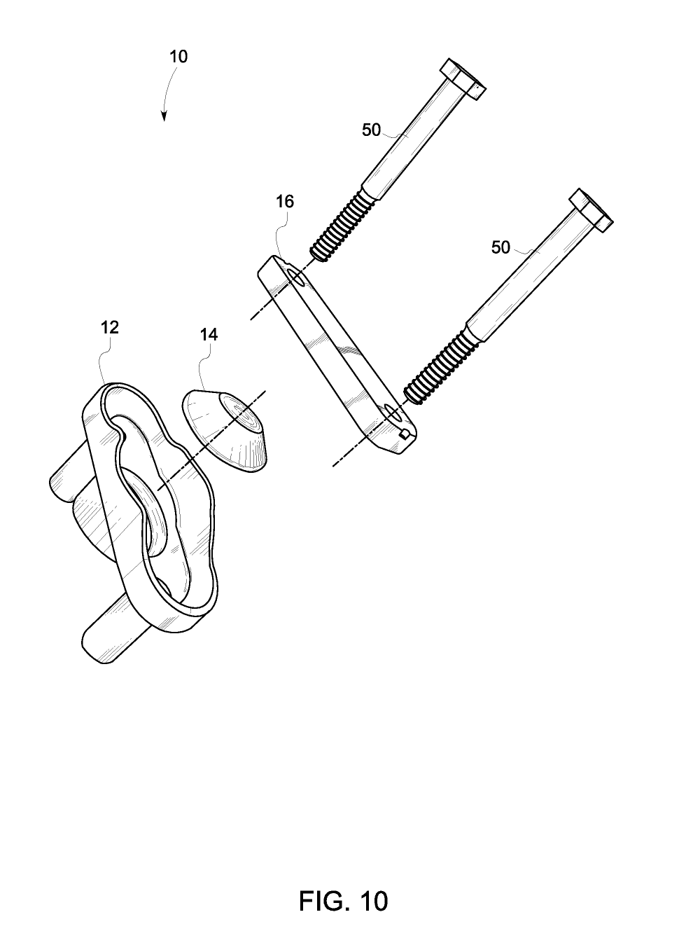

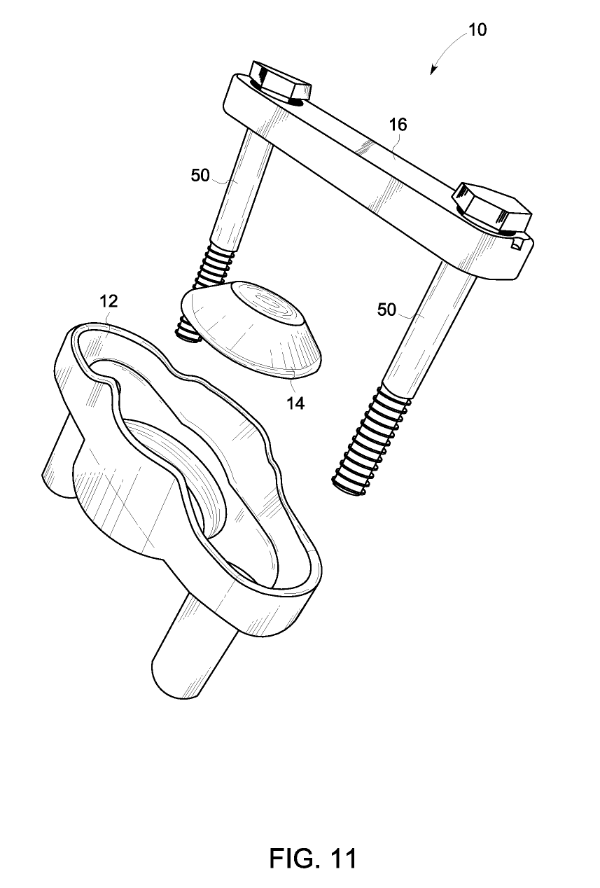

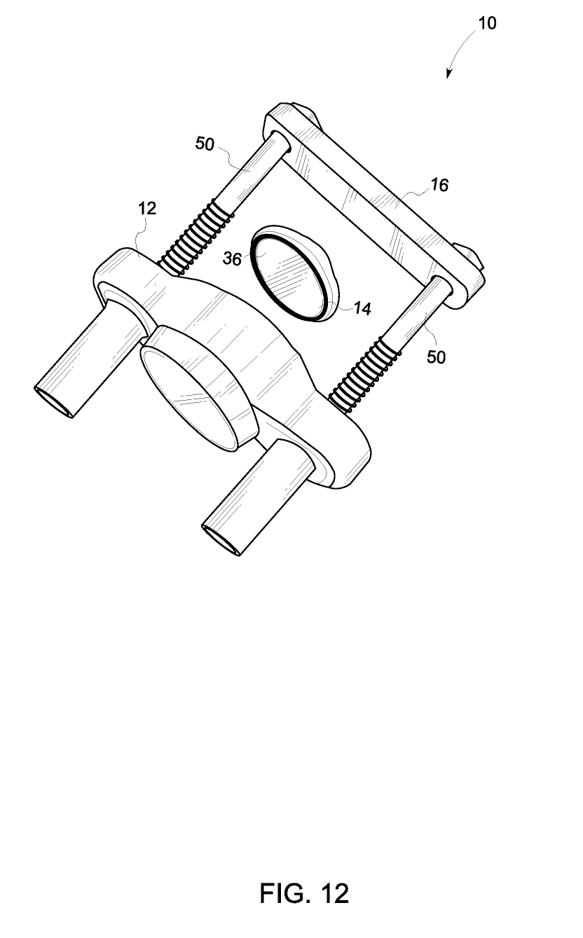

FIGS. 10-12 illustrate exploded and partially exploded views of the apparatus 10. As shown therein, and as discussed above, the pivot block 14 is configured to be received in the boss 32 in the insulative housing 12, and the load bar 16 is configured to sit atop the pivot block 14 such that the apex of the pivot block 14 is received within the detent 42 in the lower surface of the load bar 16. In this position, the load bar 16 is spaced from the floor of the arms 26, 28 such that the pivot block 14 functions as a fulcrum about which the load bar 16 pivots. Fasteners 50, such as bolts, may then be provided through the apertures 40 in the load bar 16 and the passageways 34 defined by the leg members 20, 22 to secure the apparatus 10 to a heat sink or support structure, in the manner hereinafter described.

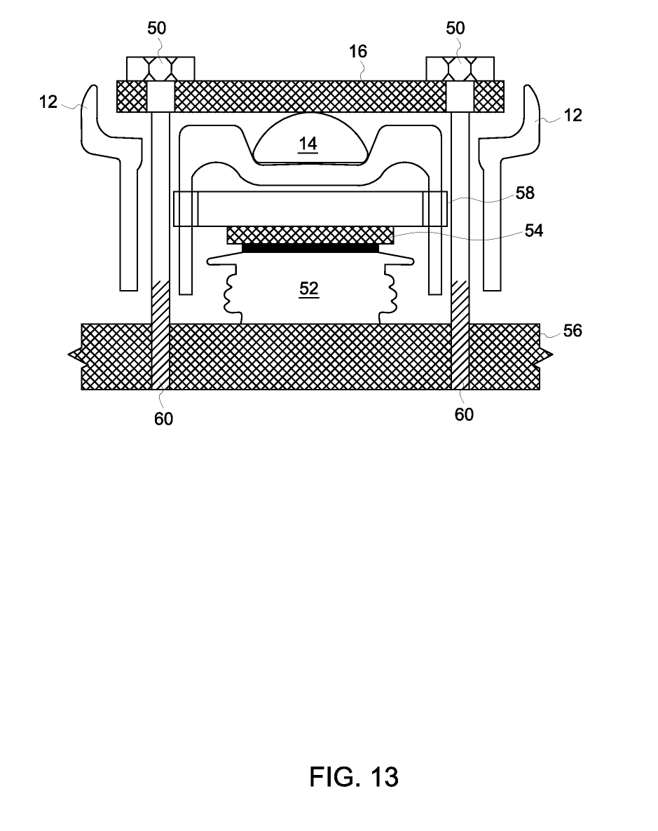

As more particularly shown in FIG. 13, in operation, the apparatus 10 may be utilized to clamp a power semiconductor or other electronic component 52, such as an SCR, and other associated components, such as a bus bar 54, between a main heat sink 56 (a first heat sink) and a secondary heat sink 58 (a second heat sink). As shown therein, the electronic component 52 is placed between the main heat sink 56 and the underside of the insulative housing 12. Bolts or other fasteners 50 are then provided through the apertures 40 and passageways 34 of the apparatus 10 and engage threaded apertures or other apertures 60 in the main heat sink 56. The bolts or other fasteners 50 are then tightened, drawing the apparatus 10 towards the main heat sink 56 and clamping the electronic component 52 and other associated components therebetween.

In particular, as the bolts or other fasteners 50 are tightened, the load bar 16 exerts a compressive force on the pivot block 14. This force is then transmitted to the insulative housing 12 and to the components to be clamped. The apparatus 10, accordingly, applies the required clamping force to the electronic component, facilitating proper electrical, mechanical, and thermal function of the device. In certain embodiments, depending upon the specifications of the electronic component and the particular application, the secondary heat sink 56 may be omitted from the assembly.

In an embodiment, the housing 12 is made of a thermoplastic material. For example, the thermoplastic material may be a glass fiber-reinforced (e.g., 30% glass fiber-reinforced) PolyEtherEtherKetone (PEEK) material. One such material is VICTREX® PEEK 450GL30 available from Victrex plc, Thornton Cleveleys, Lancashire, United Kingdom.

In embodiments, the apparatus 10 meets or exceeds electrical creepage and gap distances while maintaining a greater factor of safety to load bar failure, with increased ability to meet desired clamping forces, as compared to existing clamping devices. (“Creepage distance” means the shortest path along the insulative surface between two opposite sides of a circuit.) These requirements are met through the specific geometry and material specifications, as hereinbefore described, and which allow the apparatus 10 to exceed prior art devices in both repeatability and reliability within its application.

As alluded to above, depending on the nature of the environment in which power semiconductors or other electronic components are utilized, certain applications may have requirements for electrical creep exceed the industry standard (such as environments subject to substantial fouling or dirt). Embodiments of the apparatus 10 may exceed such heightened requirements for electrical creep through the specific geometry of the insulator body 12, the use of fillets such as fillets 30, and the placement of boss 32 within the body 12.

In addition to the above, the load bar 16 geometry and material repeatedly provide the required force at a given deflection while minimizing the risk of yielding or fracture. As discussed above, to minimize the risk of yielding, the geometry and material of the load bar 16 may be such that the yield stress of the material is well above the stress seen in operation. Moreover, the pivot block 14 is configured to distribute the load (from tightening of the fasteners 50) to the housing 12 to minimize the stress in the housing 12 and reduce the risk of the housing 12 cracking or mechanically creeping under the load.

According to an aspect, the apparatus 10 provides for more consistent clamping forces than is possible with existing clamping devices. This is due, in part, to the use of a machined load bar (as opposed to a load bar or leaf spring formed by punching) and a harder and more consistently located fulcrum (the pivot block 14). In addition, in embodiments, the apparatus 10 exhibits greater reliability as a result of obviating the risk of hydrogen embrittlement of the load bar 16, as well as reducing the risk of failure due to electrical creepage.

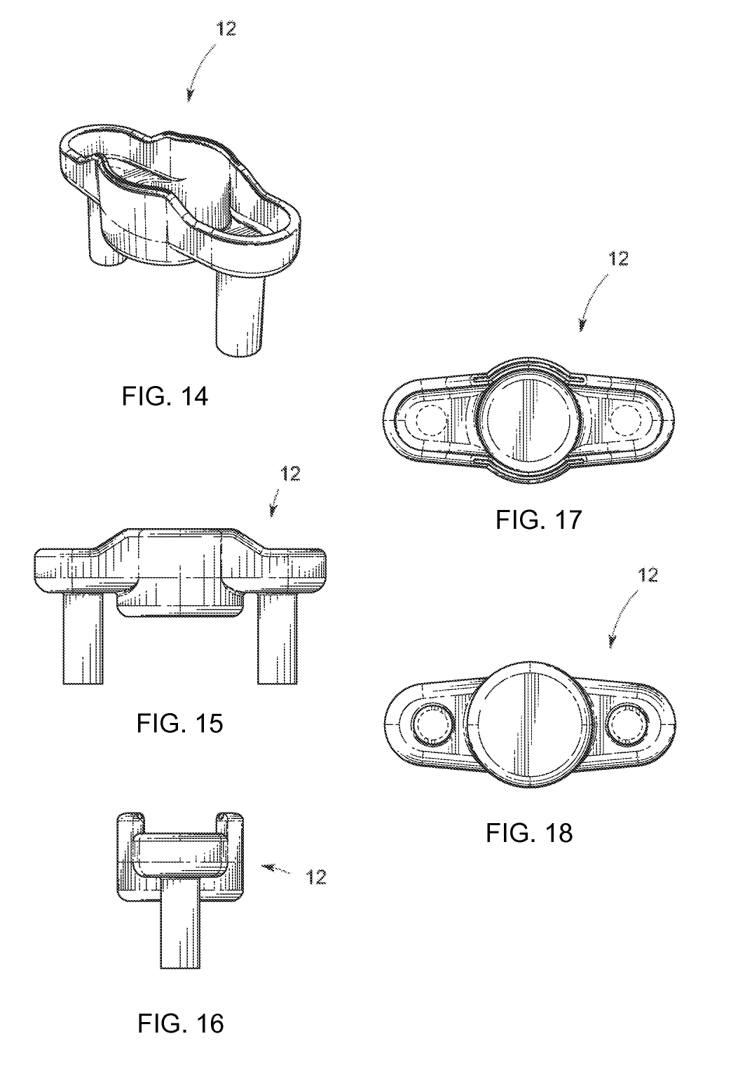

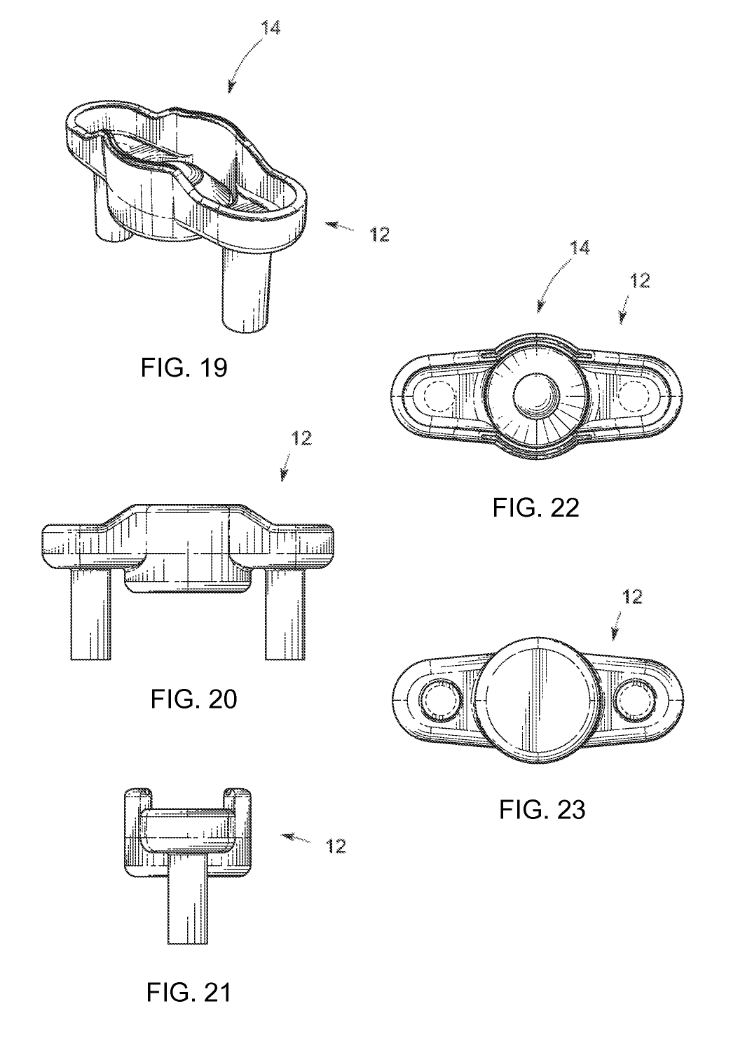

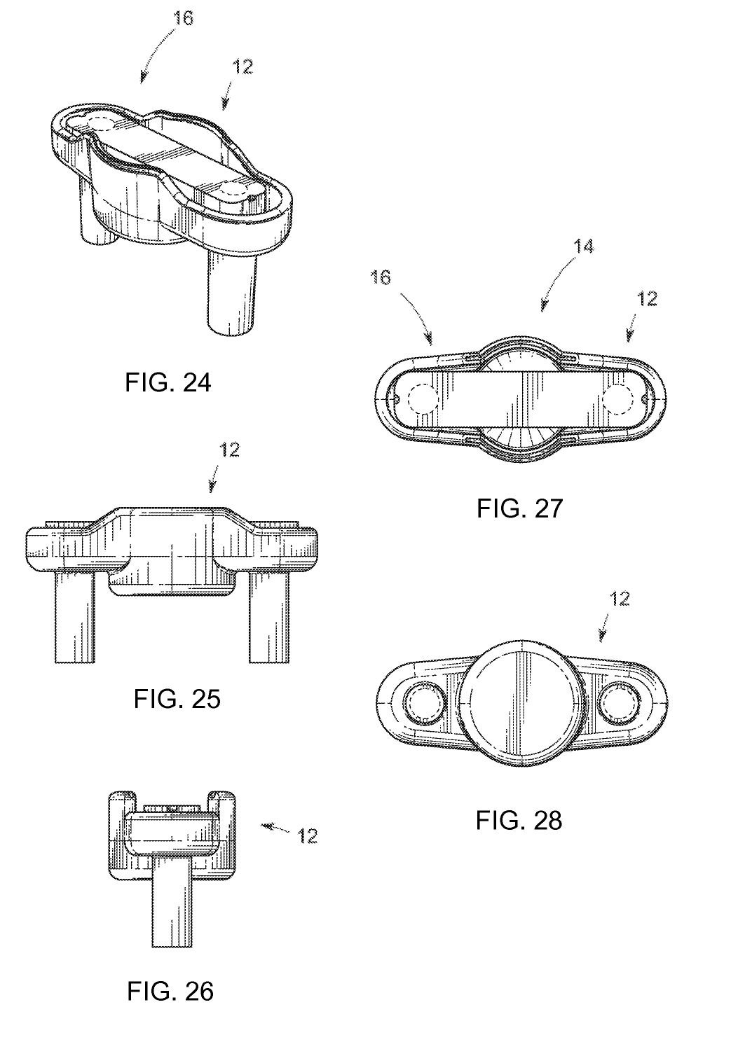

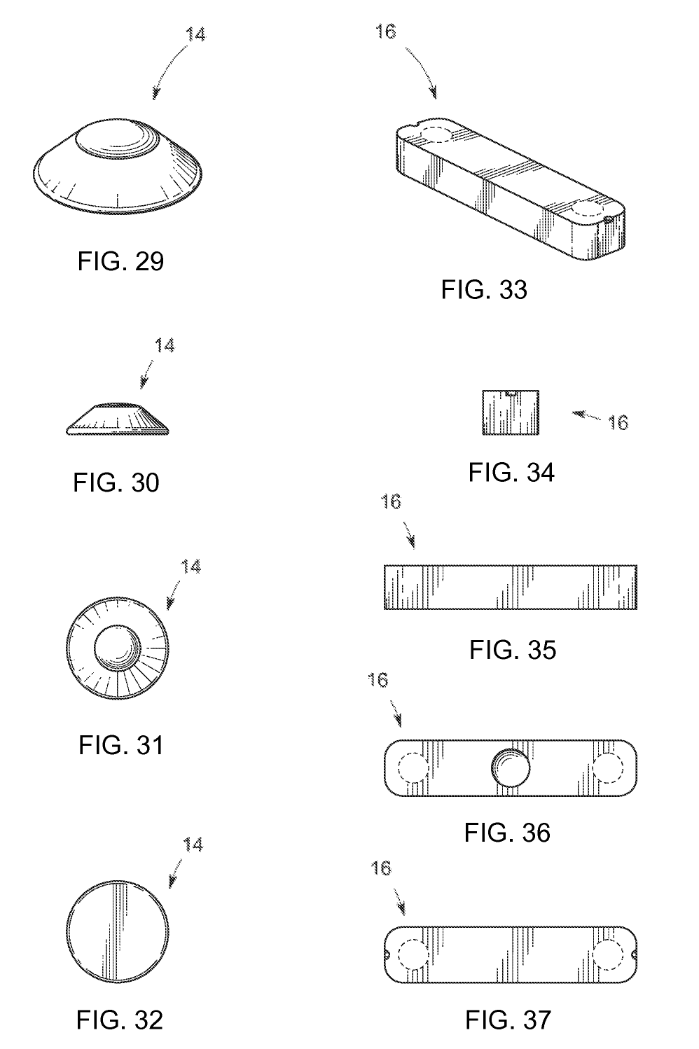

FIGS. 14-37 show additional views of various embodiments of power semiconductor clamps and components thereof. For example, FIGS. 14-18 are various views of another embodiment of a clamp housing 12. FIGS. 19-23 are various views of an embodiment of a power semiconductor clamp having a housing 12 and a pivot block 14. FIGS. 24-28 are various views of an embodiment of a power semiconductor clamp having a housing 12, a pivot block 14, and a load bar 16. FIGS. 29-32 are various views of an embodiment of a pivot block 14. FIGS. 33-37 are various views of an embodiment of a load bar 16.

In an embodiment, an electronic device comprises a support (e.g., heat sink), a power semiconductor or other electronic component operably coupled to the support, and clamp means for clamping the electronic component to the support. The clamp means comprises structure as described herein and/or shown in the figures, e.g., housing, pivot block, load bar, and bolts or other fasteners. (Examples of other fasteners include screws, rivets, cables, etc.)

In an embodiment, an apparatus includes an insulative housing including a body portion and a pair of opposed depending legs attached to the body portion, the body portion having a central recess formed therein, a pivot block configured to be disposed in the recess, and a load bar engageable with the pivot block. In an embodiment, the load bar includes a detent formed in an underside thereof and the pivot block includes a domed top having an apex configured to be received by the detent. In an embodiment, the pivot block is generally frustum-shaped. In an embodiment, the load bar is formed from stainless steel. In an embodiment, the body portion includes a generally cylindrical center portion and a pair of distal arms arranged on opposing sides of the center portion. The opposed depending legs depend from the distal arms, respectively. In an embodiment, the distal arms are integrally formed with the center portion and joined to the center portion at filleted corners. In various embodiments, the housing may be formed from plastic. In various embodiments, the pivot block may be formed from metal. In an embodiment, the pivot block has a base having a diameter that corresponds to a diameter of the recess. In an embodiment, the load bar is pivotable about the pivot block. In an embodiment, the body portion includes a generally cylindrical center portion and a pair of distal arms arranged on opposing sides of the center portion. The opposed depending legs may be respectively attached to the distal arms. The opposed depending legs and distal arms define respective passageways that extend through the opposed depending legs and distal arms. The load bar defines a pair of opposed throughbores that are spaced apart by a first distance corresponding to a second distance between the passageways of the opposed depending legs and distal arms. In an embodiment, the load bar includes a detent formed in an underside thereof and the pivot block includes a domed top having an apex configured to be received by the detent.

In an embodiment, an electronic device includes a support, a power semiconductor or other electronic component operably coupled to the support, and a clamping apparatus for clamping the electronic component to the support. The clamping apparatus including an insulative housing including a body portion and a pair of opposed depending legs, the body portion having a central recess formed therein, a pivot block configured to be disposed in the recess, and a load bar engageable with the pivot block. In an embodiment, the load bar includes a detent formed in an underside thereof and the pivot block includes a domed top having an apex configured to be received by the detent. In an embodiment, the body portion includes a generally cylindrical center portion and a pair of distal arms arranged on opposing sides of the center portion, wherein the opposed depending legs depend from the distal arms, respectively. In an embodiment, the distal arms are integrally formed with the center portion and joined to the center portion at filleted corners. In an embodiment, the body portion includes a generally cylindrical center portion and a pair of distal arms arranged on opposing sides of the center portion. The opposed depending legs are respectively attached to the distal arms. The opposed depending legs and distal arms define respective passageways that extend through the opposed depending legs and distal arms. The load bar defines a pair of opposed throughbores that are spaced apart by a first distance corresponding to a second distance between the passageways of the opposed depending legs and distal arms. In an embodiment, the load bar includes a detent formed in an underside thereof, the pivot block includes a domed top having an apex configured to be received by the detent, and the load bar is pivotable about the pivot block. In an embodiment, the housing is formed from plastic, the load bar is formed from metal, and the pivot block is formed from metal.

In an embodiment, an electronic device includes an insulative housing including a body portion and a pair of opposed depending legs, the body portion having a central recess formed therein, a pivot disposed in the recess, and a load bar engageable with the pivot block. The body portion includes a generally cylindrical center portion and a pair of distal arms arranged on opposing sides of the center portion. The opposed depending legs are respectively attached to the distal arms. The opposed depending legs and distal arms define respective passageways that extend through the opposed depending legs and distal arms. The load bar defines a pair of opposed throughbores that are spaced apart by a first distance corresponding to a second distance between the passageways of the opposed depending legs and distal arms. The load bar includes a detent formed in an underside thereof, and the pivot block includes a domed top having an apex configured to be received by the detent. The electronic device also includes a heat sink having two apertures spaced apart from one another by a third distance that corresponds to the first and second distances, a power semiconductor or other electronic component operably coupled to the heat sink between the two apertures, and first and second fasteners. The load bar engages the pivot block, with the apex of the domed top of the pivot block being received in the detent of the load bar. The first and second fasteners are respectively positioned through the opposed throughbores of the load bar, through the passageways of the opposed depending legs and distal arms, and through the apertures of the heat sink, for attaching the apparatus to the heat sink such that the load bar presses on the pivot block, the pivot block presses on the body portion, and the body portion clamps the electronic component to the heat sink.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting and are exemplary embodiments. Many other embodiments will be apparent to those of skill in the art upon reviewing the above description. The terms “including” and “in which” are used as the plain-English equivalents of the respective terms “comprising” and “wherein.” Moreover, the terms “first,” “second,” “third,” “upper,” “lower,” “bottom,” “top,” etc. are used merely as labels, and are not intended to impose numerical or positional requirements on their objects.

This written description uses examples to disclose several embodiments of the invention, including the best mode, and also to enable one of ordinary skill in the art to practice the embodiments of invention, including making and using any devices or systems and performing any incorporated methods.

As used herein, an element or step recited in the singular and proceeded with the word “a” or “an” should be understood as not excluding plural of the elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

Since certain changes may be made in the embodiments described herein without departing from the spirit and scope of the invention herein involved, it is intended that all of the subject matter of the above description or shown in the accompanying drawings shall be interpreted merely as examples illustrating the inventive concept herein and shall not be construed as limiting the invention.

What is claimed is:

1. An apparatus, comprising:
an insulative housing including a body portion and a pair of opposed depending legs attached to the body portion, the body portion having a central recess formed therein;
a pivot block configured to be disposed in the recess; and
a load bar engageable with the pivot block.

2. The apparatus of claim 1, wherein:
the load bar includes a detent formed in an underside thereof; and
the pivot block includes a domed top having an apex configured to be received by the detent.

3. The apparatus of claim 2, wherein:
the pivot block is generally frustum-shaped.

4. The apparatus of claim 1, wherein:
the load bar comprises stainless steel.

5. The apparatus of claim 1, wherein:
the body portion includes a generally cylindrical center portion and a pair of distal arms arranged on opposing sides of the center portion; and
wherein the opposed depending legs depend from the distal arms, respectively.

6. The apparatus of claim 5, wherein:
the distal arms are integrally formed with the center portion and joined to the center portion at filleted corners.

7. The apparatus of claim 1, wherein:
the housing comprises plastic.

8. The apparatus of claim 1, wherein:
the pivot block comprises metal.

9. The apparatus of claim 1, wherein:
the pivot block has a base having a diameter that corresponds to a diameter of the recess.

10. The apparatus of claim 1, wherein:
the load bar is pivotable about the pivot block.

11. The apparatus of claim 1, wherein:
the body portion includes a generally cylindrical center portion and a pair of distal arms arranged on opposing sides of the center portion;
the opposed depending legs are respectively attached to the distal arms;
the opposed depending legs and distal arms define respective passageways that extend through the opposed depending legs and distal arms; and
the load bar defines a pair of opposed throughbores that are spaced apart by a first distance corresponding to a second distance between the passageways of the opposed depending legs and distal arms.

12. The apparatus of claim 11, wherein:
the load bar includes a detent formed in an underside thereof; and
the pivot block includes a domed top having an apex configured to be received by the detent.

13. An electronic device, comprising:
the apparatus of claim 12;
a heat sink having two apertures spaced apart from one another by a third distance that corresponds to the first and second distances;
an electronic component operably coupled to the heat sink between the two apertures; and
first and second fasteners;
wherein the pivot block is disposed in the recess;
the load bar engages the pivot block, with the apex of the domed top of the pivot block being received in the detent of the load bar; and
the first and second fasteners are respectively positioned through the opposed throughbores of the load bar, through the passageways of the opposed depending legs and distal arms, and through the apertures of the heat sink, for attaching the apparatus to the heat sink such that the load bar presses on the pivot block, the pivot block presses on the body portion, and the body portion clamps the electronic component to the heat sink.

14. An electronic device, comprising:
a support;
an electronic component operably coupled to the support; and
a clamping apparatus for clamping the electronic component to the support, the clamping apparatus including an insulative housing including a body portion and a pair of opposed depending legs attached to the body portion, the body portion having a central recess formed therein, a pivot block disposed in the recess, and a load bar engageable with the pivot block.

15. The electronic device of claim 14, wherein:
the load bar includes a detent formed in an underside thereof; and
the pivot block includes a domed top having an apex configured to be received by the detent.

16. The electronic device of claim 14, wherein:
the body portion includes a generally cylindrical center portion and a pair of distal arms arranged on opposing sides of the center portion; and
wherein the opposed depending legs depend from the distal arms, respectively.

17. The electronic device of claim 14, wherein:
the distal arms are integrally formed with the center portion and joined to the center portion at filleted corners.

18. The electronic device of claim 14, wherein:
the body portion includes a generally cylindrical center portion and a pair of distal arms arranged on opposing sides of the center portion;
the opposed depending legs are respectively attached to the distal arms;
the opposed depending legs and distal arms define respective passageways that extend through the opposed depending legs and distal arms; and
the load bar defines a pair of opposed throughbores that are spaced apart by a first distance corresponding to a second distance between the passageways of the opposed depending legs and distal arms.

19. The electronic device of claim 18, wherein:
the load bar includes a detent formed in an underside thereof;
the pivot block includes a domed top having an apex configured to be received by the detent; and
the load bar is pivotable about the pivot block.

20. The electronic device of claim 18, wherein:
the housing comprises plastic;
the load bar comprises a first metal; and
the pivot block comprises one of the first metal or a second metal.
